(19) United States
(12) Patent Application Publication
(10) Pub. No.: US 2021/0132160 A1
(43) Pub. Date: May 6, 2021

(54) AUTOMATED PIM MATRIX TEST FIXTURE AND METHODS OF OPERATING THE SAME

(71) Applicant: CommScope Technologies LLC, Hickory, NC (US)

(72) Inventors: Thomas Sheehe, Allen, TX (US); Troy I. Vanderhoof, Prosper, TX (US)

(21) Appl. No.: 17/083,994

(22) Filed: Oct. 29, 2020

Related U.S. Application Data
(60) Provisional application No. 62/927,886, filed on Oct. 30, 2019.

(51) Int. Cl. G01R 31/68; H01Q 1/24; H01R 43/26

(52) U.S. Cl. CPC G01R 31/68; H01R 2201/20; H01R 43/26; H01Q 1/24

(57) ABSTRACT

A test fixture includes a first body including a plurality of slots that are configured to receive a plurality of antenna connectors, respectively; a second body opposing the first body and including a slot that is configured to receive a test connector; and a lateral positioning component that is configured to move the second body relative to the first body so as to position the test connector across from one of the plurality of antenna connectors. The second body is further configured to push the test connector into the one of the plurality of antenna connectors across from the test connector so as to mate the test connector to the one of the plurality of antenna connectors.

### CROSS-REFERENCE TO RELATED APPLICATION

The present application claims priority to U.S. Provisional Patent Application Serial No. 62/927,886, filed Oct. 30, 2019, the entire content of which is incorporated by reference herein as if set forth in its entirety.

### BACKGROUND

Passive Intermodulation Distortion (PIM) is a form of electrical interference/signal transmission degradation that may occur with less than symmetrical interconnections and/or as electro-mechanical interconnections shift or degrade over time. Interconnections may shift due to mechanical stress, vibration, thermal cycling, and/or material degradation. PIM can be an important interconnection quality characteristic, as PIM generated by a single low quality interconnection may degrade the electrical performance of an entire RF system.

Base station antennas can be a source of PIM, which can lower the reliability, capacity, and data rate of cellular systems. It does this by limiting the sensitivity of a receiver. In some applications engineers may select channel frequencies that result in less PIM in the receive bands. But as the spectrum becomes more crowded, the ability to reduce PIM through channel frequency selection may become more difficult. Moreover, aging antenna systems and infrastructure may increase PIM. Thus, to maintain the reliability of an antenna, it is generally desirable to ensure that PIM be reduced to an acceptable level. Testing may be routinely performed on antennas to determine whether their PIM performance is within an acceptable range. This testing can either be done on-site in the field, or in a more controlled environment such as an anechoic chamber. A typical antenna can have multiple ports which require PIM testing.

FIG. 1 illustrates a conventional antenna PIM test setup 10. A test management system 100 communicates with analyzer 101 over connection 105. The analyzer 100 is connected to a single port of the antenna 102 under test. The antenna is inside an anechoic chamber 103 so as to avoid reflections and outside noise sources. The cable 106 which connects the analyzer to an antenna port passes into the test chamber 103 through a conduit 107.

PIM testing is typically performed in an anechoic chamber so as to reduce interference from reflections or other radiation sources. An operator may place an antenna in a test chamber and connect one of the antenna ports to an analyzer, which is outside the test chamber. The cable is passed from the inside of the chamber to outside the chamber through a conduit. To test a different port, it is necessary for the operator to enter the chamber and manually change the connection. When a number of ports need testing on an antenna, this entire process can result in excessively long test times.

### SUMMARY

In some embodiments of the inventive concept, a test fixture comprises a first body comprising a plurality of slots that are configured to receive a plurality of antenna connectors, respectively; a second body opposing the first body and comprising a slot that is configured to receive a test connector; and a lateral positioning component that is configured to move the second body relative to the first body so as to position the test connector across from one of the plurality of antenna connectors. The second body is further configured to push the test connector into the one of the plurality of antenna connectors across from the test connector so as to mate the test connector to the one of the plurality of antenna connectors.

In other embodiments, the plurality of antenna connectors comprises a plurality of blind mate connectors.

In still other embodiments, each of the plurality of antenna connectors comprises a flange portion, and the plurality of slots is configured to receive the plurality of flange portions of the plurality of antenna connectors, respectively, therein.

In still other embodiments, the flange portions comprise brass.

In still other embodiments, each of the plurality of antenna connectors comprises a beveled countersink opening that is configured to receive the test connector therein.

In still other embodiments, the plurality of antenna connectors are coupled to a plurality of biasing springs, respectively, which are configured to urge the plurality of antenna connectors towards the second body.

In still other embodiments, the first body comprises stainless steel.

In still other embodiments, the lateral positioning component comprises a worm drive coupled to the second body, and a motor connected to the worm drive and configured to rotate the worm drive to move the second body relative to the first body.

In still other embodiments, the motor is configured to rotate the worm drive responsive to a motor operation signal generated by a test controller.

In still other embodiments, the test controller is configured to count a number of times the test connector has been mated to ones of the plurality of connectors.

In still other embodiments, the slot in the second body is a first slot and the test connector is a first test connector, and the second body further comprises a second slot that is configured to receive a second test connector.

In still other embodiments, the second test connector does not mate with any of the plurality of antenna connectors when the first test connector mates with the one of the plurality of antenna test connectors.

In still other embodiments, each of the test connector and the plurality of antenna connectors comprise a 4.3-10 blind mate connector.

In some embodiments of the inventive concept, a method for measuring an attribute of multiple antenna ports comprises automatically mating a test connector to a first antenna connector, in response to initiation of a test sequence, taking a first measurement with the analyzer, automatically unmating the test connector from the first antenna connector, automatically mating the test connector to a second antenna connector, and taking a second measurement with a first analyzer.

In further embodiments, the method further comprises counting a number of times each cable is mated.

In still further embodiments, controlling the test fixture and taking a measurement are performed without the intervention of an operator after an initial command.

In still further embodiments, the method further comprises, in response to initiation of the test sequence: automatically mating a second test connector to a third antenna connector and taking a third measurement with a second analyzer.

In still further embodiments, the first analyzer is configured to measure a different frequency range than the second analyzer.

In some embodiments of the inventive concept, an antenna system comprises a test chamber; a test fixture inside the test chamber; an antenna inside the test chamber; an analyzer outside the test chamber; a plurality of jumper cables connected from a plurality of antenna ports to the test fixture; at least one test cable connected from the test fixture, through a conduit, to the analyzer; and a computer. The computer is configured to send a command to the test fixture. The test fixture is configured to mate the at least one test cable to one of the plurality of jumper cables in response to the command. The test fixture is further configured to mate the at least one test cable to a second one of the plurality of jumper cables in response to east least one subsequent command from the computer without an operator entering the test chamber.

In other embodiments, the test fixture is configured to move a first connector of the at least one test cable along a linear track to align with a selected second connector of the jumper cables.

In still other embodiments, the test fixture is configured to move the first connector towards the second connector to mate the first connector to the second connector.

In still other embodiments, the analyzer is a first analyzer and the at least one test cable is a first test cable, the system further comprising: a second analyzer and a second test cable. The second test cable being connected from the test fixture, through a conduit, to the second analyzer. The first analyzer is configured to operate in a first frequency range. The second analyzer is configured to operate in a second frequency range.

In still other embodiments, the first frequency range and the second frequency range do not overlap.

Other apparatus, systems, assemblies, and/or articles of manufacture, according to embodiments of the inventive concept, will be or become apparent to one with skill in the art upon review of the following drawings and detailed description. It is intended that all such additional apparatus, systems, assemblies, and/or articles of manufacture be included within this description, be within the scope of the present inventive concept, and be protected by the accompanying claims.

### BRIEF DESCRIPTION OF THE DRAWINGS

FIG. 1 is a block diagram of a typical antenna test setup.

FIGS. 2-4 are block diagrams of test setups in accordance with some embodiments of the inventive concept.

FIG. 3 is a block diagram of an antenna test setup including a test fixture and two analyzers.

FIG. 4 is a block diagram of an antenna test setup including two test fixtures and two analyzers.

FIG. 5 is a block diagram of a test fixture according to some embodiments of the inventive concept.

FIG. 6 is a perspective view of the test fixture of FIG. 5 enclosed in a housing according to some embodiments of the inventive concept.

FIGS. 7A and 7B are elevation views illustrating a connector that may be used as an antenna connector or a test connector in accordance with some embodiments of the inventive concept.

FIG. 8 is a perspective view of a test connector mated to an antenna connector in accordance with some embodiments of the inventive concept.

FIGS. 9-11 are flowcharts that illustrate operations of a test setup according to some embodiments of the inventive concept.

FIG. 12 is a block diagram of a test management system according to some embodiments of the inventive concept.

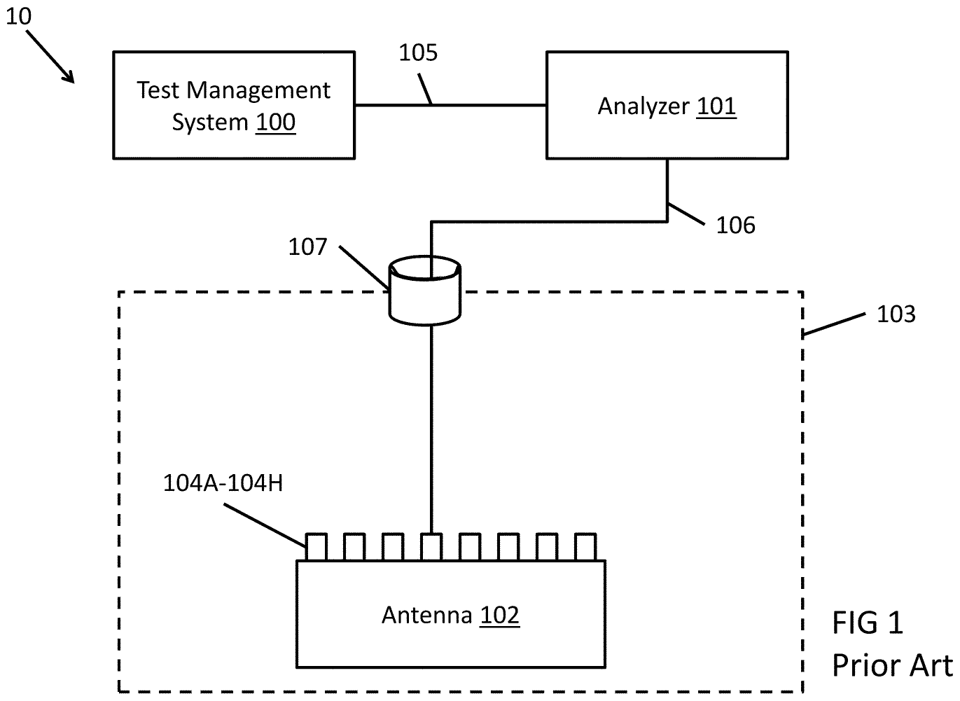

### DETAILED DESCRIPTION

In the following detailed description, numerous specific details are set forth to provide a thorough understanding of embodiments of the present disclosure. However, it will be understood by those skilled in the art that embodiments of the present invention may be practiced without these specific details. In some instances, well-known methods, procedures, components, and circuits have not been described in detail so as not to obscure the present disclosure. Aspects described with respect to one embodiment may be incorporated in different embodiments although not specifically described relative thereto. That is, all embodiments and/or features of any embodiments can be combined in any way and/or combination.

Some embodiments of the inventive concept stem from a realization that due to the sensitivity of Passive Intermodulation Distortion (PIM) measurements, a test operator must connect each port of a device under test individually. This result in an operator entering and exiting an anechoic PIM chamber multiple times during the test of a single antenna, which can be time consuming and inefficient. Automation of PIM testing may introduce additional technical considerations as existing electrical switches and relays may introduce PIM themselves and, therefore, may not be used reliability in PIM testing.

Some embodiments of the inventive concept provide systems and methods for automated PIM testing of antennas. The described embodiments may provide for faster test times by reducing the amount of time required for an operator to manually change cables. Other benefits of the present embodiments include allowing fewer operators to oversee a larger number of concurrent tests, which may reduce the risk of user error. While the present embodiments can be used for a variety of test scenarios, they may be particularly well suited for PIM testing, as the provided test fixture provides a way to change cable connections without adding a substantial amount of PIM distortion.

There are two main methods of performing PIM testing. The first is reflective or reverse PIM testing. This method of testing involves sending two RF signals to an antenna and uses the same port to measure the reflected signal. Typically, either two fixed frequencies are selected or one of the frequencies is fixed while the other is swept across a range. The other main method of PIM testing is forward PIM testing. Forward PIM testing of an antenna does not measure the reflected signal, but rather measures the propagated signal either with a filter network or an external antenna. This type of testing is typically performed in an anechoic chamber as the external antenna is susceptible to pick up noise from other sources.

The test fixture according to embodiments of the inventive concept includes a plurality of slots for antenna connectors with an opposing slot for a test connector. The fixture is able to move the test connector along the row of antenna connectors so that it may be positioned to mate with any of the antenna connectors in the row. This allows for the operator to perform a test on a number of antenna ports without the need to manually change the cables. Typically PIM testing is performed in an anechoic test chamber. This means that any manual changing of cables requires an operator to stop the testing so that the operator may enter the chamber, make the change, and exit the chamber. By providing a test fixture as described in the embodiments herein, this overhead in terms of time and manual reconfiguration may be reduced.

In some embodiments, the test fixture includes a controller, which may perform a number of functions. The controller may receive communications from a test management system (e.g. a computer). In response to commands from the test management system, the controller may move the test connector as needed to mate with the desired antenna connector. The controller may also count the number of mating cycles for each connector to allow for preventive maintenance.

The test management system may be configured to run a test sequence that includes the testing of multiple ports without any operator intervention. In some embodiments, the test fixture may receive multiple test connectors from multiple analyzers. In this way, tests can be performed on multiple ports across different frequencies. By using multiple test fixtures, a larger number of antenna ports may be tested in a single test run.

In some embodiments, changing the connectors in the fixture either for preventive maintenance or any other reason can be accomplished easily as the connectors are held in place by being received in a slot, which can release the cables without the need of any tools.

Embodiments of the present invention will now be discussed in greater detail with reference to the accompanying figures.

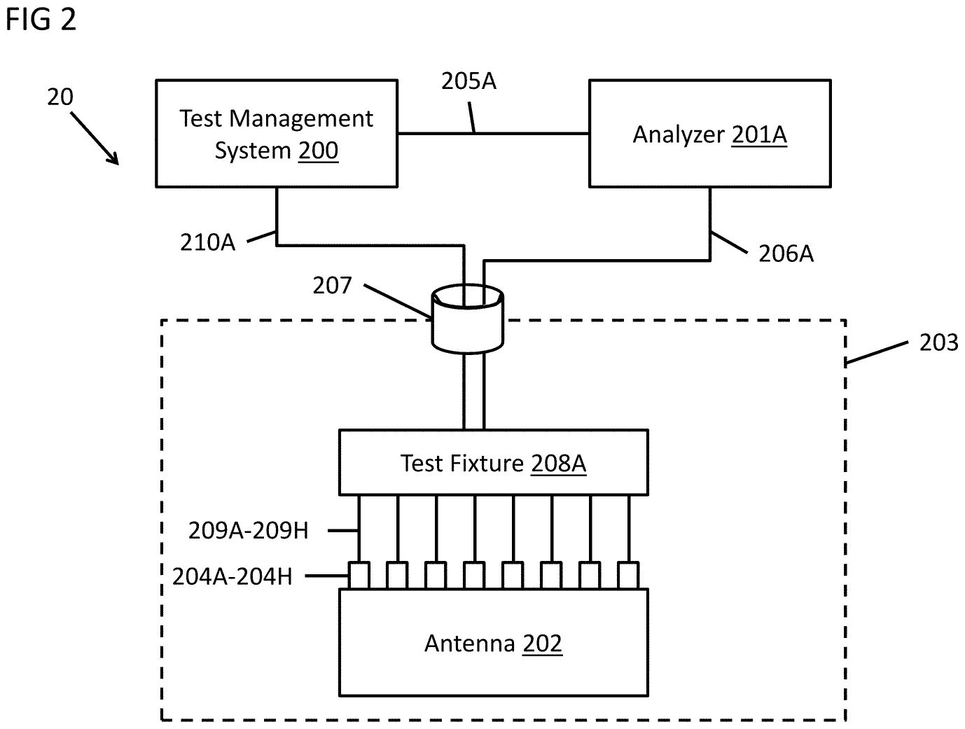

FIG. 2 illustrates a test setup 20 in accordance with some embodiments of the inventive concept. As shown in FIG. 2, a test setup for performing PIM testing, for example, on an antenna, may include a test fixture 208A. The test fixture 208A is inside the test chamber 203 with the antenna. The test fixture 208A receives connections from the test management system 200, the analyzer 201A, and antenna ports 204A-204H. A test management system 200 communicates with the test fixture 208A via a communication cable 210A. Cables that go from outside the test chamber 203 to the inside may pass through a conduit or waveguide 207.

Providing a test fixture may allow for the connection from analyzer 201A to be mated with any of the antenna ports connected to the test fixture 208A. The antenna ports may be accessed by way of antenna cables 209A-209H ending in connectors 204A-204H. Control of which connectors of the test fixture 208A are mated to the antenna cables 209A-209H may be accomplished by commands sent from the test management system 200 to the test fixture 208A. By using the test fixture 208A to change which connectors are mated, an operator is not required to enter the chamber and manually change the connections. Test fixture 208A introduces only a very low amount of PIM to the measurements as only a single additional connection is added between the PIM analyzer 201A and the unit under test, i.e., antenna 202. As a result, the measurements accurately reflect the performance of the antenna. Test management system 200 is also in communication with the analyzer 201A so that measurements can be performed and the data reported back to the test management system, where it can be correlated with the port which was connected at the time of the measurement.

Analyzer 201A is a PIM analyzer in some embodiments of the inventive concept. In some embodiments, the analyzer 201A may be configured to perform reflective PIM testing. Such an analyzer emits RF signals on the test port, and measures the reflected signal. It will be understood that other types of measurements of various kinds can be made using the same test setup in accordance with other embodiments of the inventive concept. For example, surge testing, electrical fast transient (EFT) testing, conducted emissions testing, conducted immunity testing, and the like. The direct connections made by the test fixture can be advantageous over electrical switches or relays in these tests as well.

As shown in FIG. 2, antenna 202 has a number of ports. In this embodiment, eight ports are shown, but antennas of a varying number of ports can be supported. Likewise, the test fixture is shown with eight antenna ports, but it will be understood by a person of ordinary skill in the art that a different number of ports can be in accordance with other embodiments of the inventive concept. Additionally, a test operator does not necessarily always test every port of an antenna; therefore, there may be antenna ports and/or test fixture ports that remain disconnected during a test.

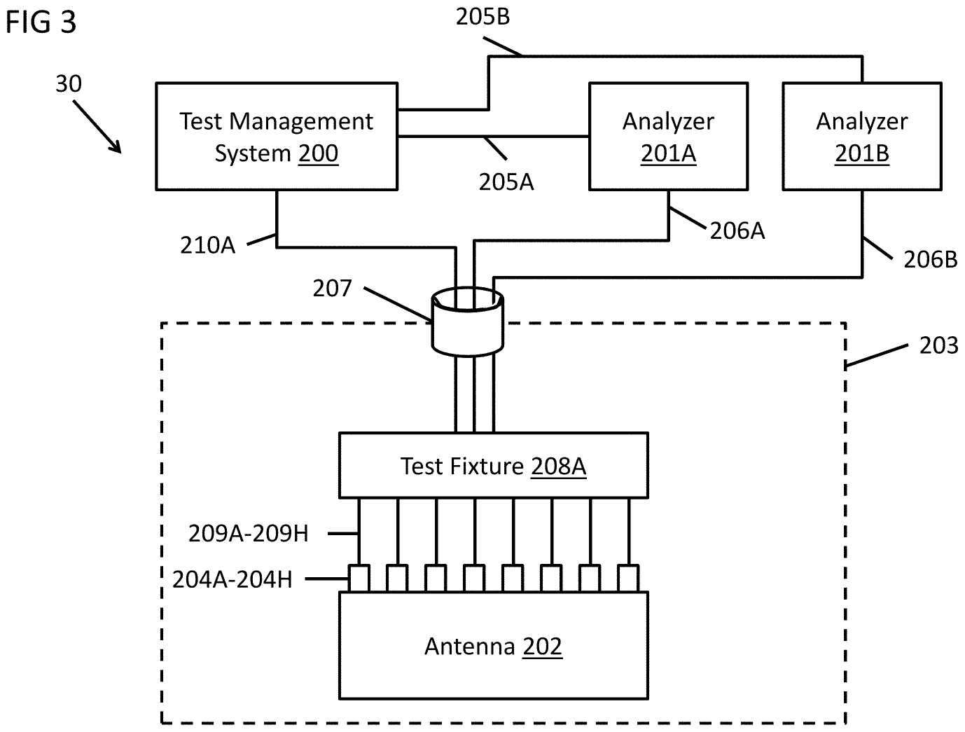

FIG. 3 illustrates a test setup 30 in accordance with some embodiments of the inventive concept. Referring to FIG. 3, an additional analyzer 201B may be included in the test setup. In this embodiment, analyzers 201A and 201B connect to test fixture 208A by cables 206A and 206B respectively. Test fixture 208A according to the embodiments of FIG. 3 can mate either of the analyzer cables 206A, 206B to any of the antenna ports connected to the test fixture 208A by way of the antenna cables 209A-209H ending in connectors 204A-204H. In this manner, each analyzer 201A, 201B can be configured to take PIM measurements over different frequency ranges. These frequency ranges can be the same, overlapping, or non-overlapping ranges in accordance with different embodiments of the inventive concept. A test procedure using this setup can test a number of antenna ports using one or both of the analyzers in a single test run. By using multiple analyzers 201A, 201B connected to the same test fixture 208A, test time can be reduced over other methods, which may require manual connection changes between each test. It will be understood that while two analyzers 201A, 201b are shown, additional analyzers can be included in accordance with other embodiments of the inventive concept.

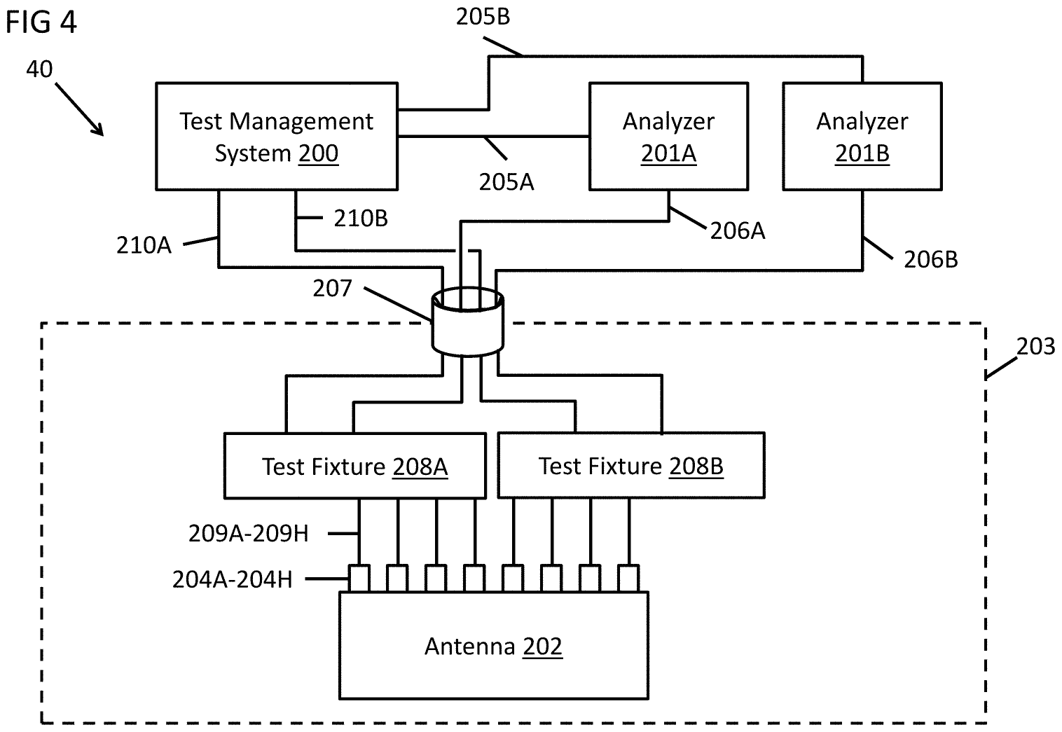

FIG. 4 illustrates a test setup 40 in accordance with some embodiments of the inventive concept. Referring to FIG. 4, compared to the test setup 30 of FIG. 3, an additional test fixture 208B can also be used. By using more than one test fixture 208A, 208B, more antenna ports can be tested in a single test run than can be tested using a single test fixture due to the capacity of the single test fixture. As shown in FIG. 4, each test fixture 208A and 208B can communicate with the test management system 200, and to a respective analyzer 201A or 201B. It will be understood, however, that different combinations are possible including multiple analyzers connected to one or both of the test fixtures 208A, 208B. Additionally, larger numbers of test fixtures may be added to the test setup 40 in other embodiments of the inventive concept. By combining different analyzers and test fixtures in this way, multiple different antennas with varying numbers of ports and test requirements can be tested.

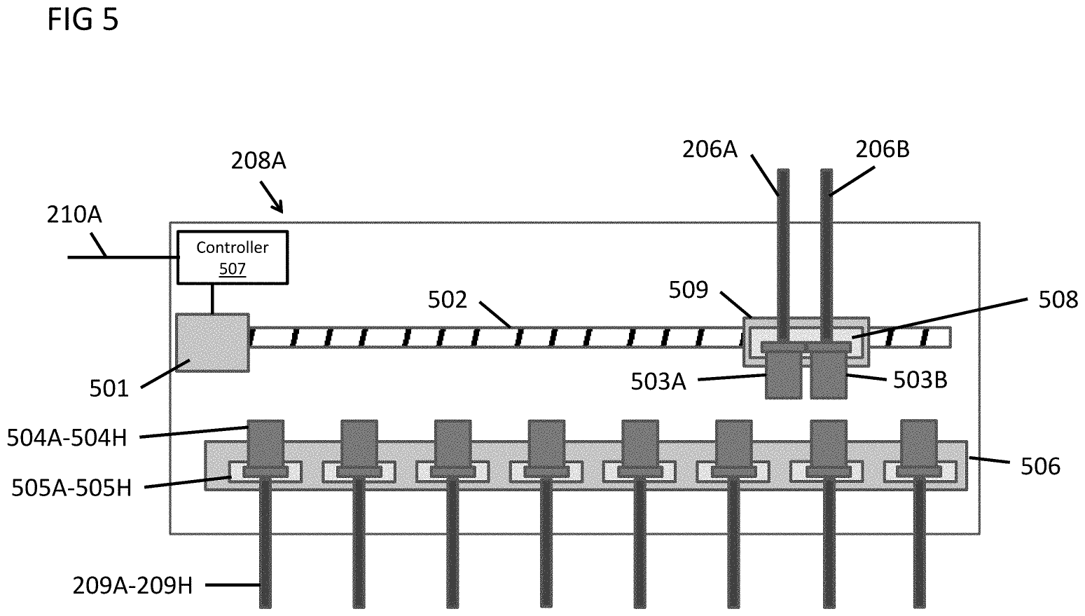

FIG. 5 illustrates test fixture 208A according to some embodiments of the inventive concept. As shown in FIG. 5, there are two opposing groups of cables with connectors facing each other. Test cables 206A and 206B ending in connectors 503A and 503B; and antenna cables 209A-209H ending in connectors 504A-504H. Each of these connectors is held in place in the fixture in slots 508 or 505A-505H. Structure 506, which holds slots 505A-505H may be fixed in place, while structure 509 which holds slots 508 may move linearly in a direction that is lateral to the opposing connectors 504A-504H. Structures 509 and 506 may be constructed of stainless steel and portions of the connectors 503A-503B and connectors 504A-504H may also be constructed of stainless steel.

Structure 508 which rests on structure 509 can move towards and away from the connectors 504A-504H. In this way, when a pair of connectors, i.e., a test connector 503A, 503B and an antenna connector 504A-504H, is desired to be connected together, first they are aligned in the first direction by moving the structure 509 laterally, then they are connected by moving structure 508 towards the opposing group of connectors so that the pair connects. In embodiments such as that shown in FIG. 5 where there are two test connectors 503A, 503B, they are spaced in such a way that one or the other can be connected to any of the antenna connectors 504A-504H without the other interfering.

Structure 509 may be moved laterally by way of a worm drive 502. It will be understood that other drive mechanisms may be used in other embodiments of the inventive concept. Worm drive 502 is driven by a motor 501, which is directly controlled by the test fixture controller 507. The forward motion of the test connectors 503A, 503B may also directly controlled by the test fixture controller 507. In turn, the controller 507 communicates over cable 210A to a test management system 200. In this way, the test management system 200 can send commands to the controller, such as a command to align a specific pair of connectors, i.e., a test connector and an antenna connector, and the test fixture controller 507 can communicate with the motor 501 to perform that task.

Structure 508 may be moved linearly towards and away from the opposing connectors 504A-504H. In some embodiments, the motion is motor driven, and the motor is controlled by the test fixture controller 507. The motor may turn a worm drive or any other type of linear drive.

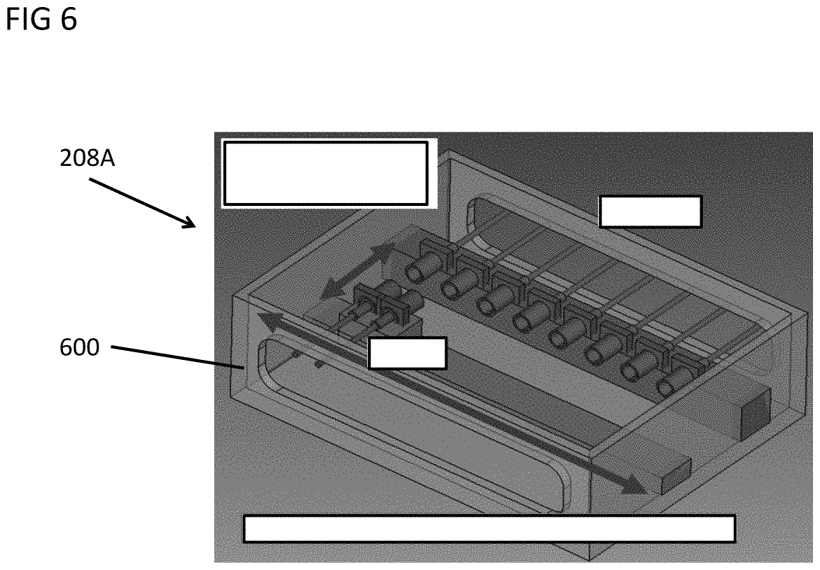

FIG. 6 is a perspective view of the test fixture of FIG. 5 enclosed in a housing. Referring to FIG. 6, the test fixture 208A components, according to some embodiments of the inventive concept, are enclosed within an enclosure 600 that has openings for cables to pass through.

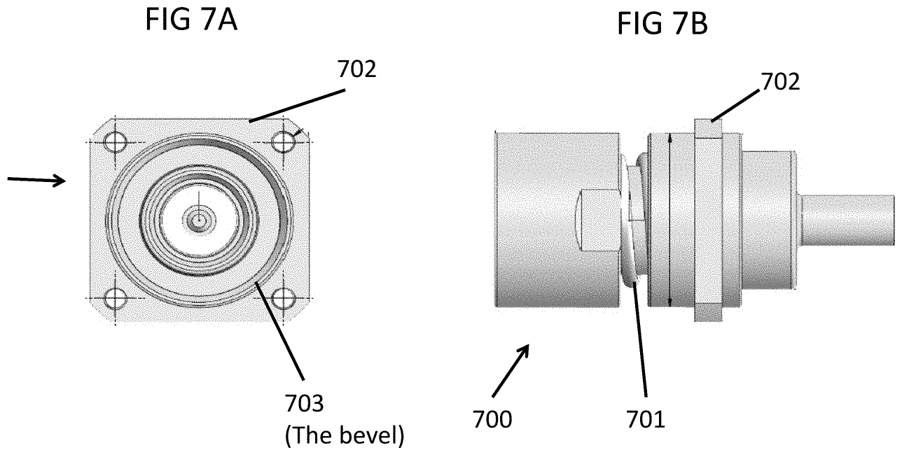

FIGS. 7A and 7B are elevation views illustrating a connector that may be used as an antenna connector or a test connector in accordance with some embodiments of the inventive concept. Referring to FIGS. 7A and 7B, a connector 700, which may be used for either the antenna connectors 504A-504H or test connectors 503A-503B is illustrated. Certain features of connector 700 may be advantageous for use in the test fixture 208A. The connector 700 may be a blind mate connector, which allows the connector to be mated without needing to rotate the connector. This means that when the test fixture moves the connector forward, it can mate, and when the connector moves away it will disconnect without any further action such as screwing or latching. Additionally, the flange 702 may facilitate holding the connector into the slots provided on structures 505A-505H and 508. The flange 702 may be constructed of brass with the body of the connector 700 being stainless steel according to some embodiments of the inventive concept. An opening in the connector 700 may be bevel shaped 703 to allow for a slight misalignment of mating connectors to be corrected by the mating connectors sliding laterally in response to contact with the bevel shaped edge 703. Thus, the opening of a female connector may be bevel shaped 703 to form a countersink to facilitate receiving a male connector therein. A biasing spring 701 may a good connection by urging the connector 700 forward when the connector 700 is pushed forward by, for example, movement of a test fixture towards connectors connected to antenna ports. In some embodiments, the connector 700 may be a flange mount 4.3-10 blind mate connector. It will be understood that the connectors used as antenna connectors 504A-504H may be countersink connectors to receive male test connectors 503A-503B or vice versa. In some embodiments, the test connectors 503A-503B may be configured to be pushed forward towards the antenna connectors 504A-504H to engage the test connectors 504A-504H by the test fixture on which the test connectors 503A-503B are installed and then to disengage and move linearly to the next set of antenna ports to be tested. The test connectors 503A-503B may then be pushed forward to engage the ones of the antenna connectors 504A-504H associated with the next set of antenna ports to be tested.

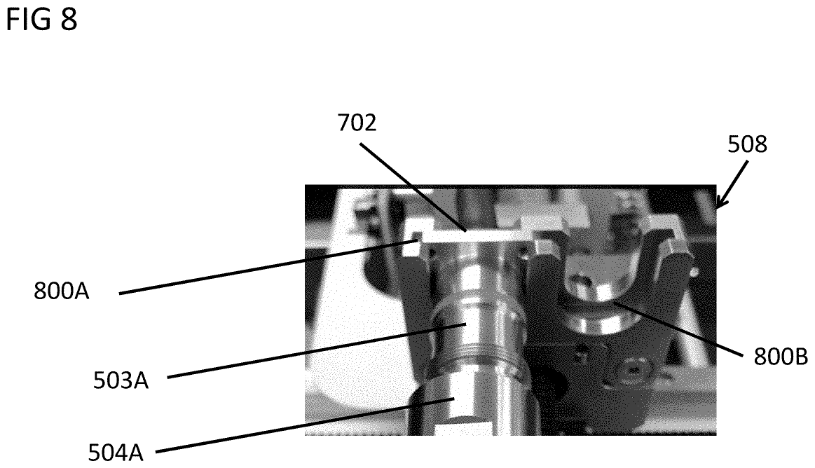

FIG. 8 is a perspective view of a test connector mated to an antenna connector in accordance with some embodiments of the inventive concept. As shown in FIG. 8, a male test connector 503A is engaged with a female connector 504A. Test connectors, such as 503A, and antenna connectors, such as 504A, both may rest in slots such as is shown in FIG. 8. The embodiment of structure 508 shown in FIG. 8 contains two slots 800A, 800B, each capable of holding a test connector. It will be understood that more or less slots could be made into structures 506 or 508, either for holding antenna connectors or test connectors, respectively, in accordance with various embodiments of the inventive concept. The flange 702 may be configured to easily slide into the slot 800A or 800B. The flange and slot design may facilitate easy insertion and removal of connectors to and from the test fixture 208A, 208B. Whether as a part of initial setup, routine maintenance, or replacing bad cables, being able to remove and replace cables and connectors easily helps reduce the amount of time needed in maintaining an operating a test setup. The slots 800A and 800B additionally may not require the use of any tool to insert a new connector. Finally, the lack of any screw mounting hardware removes differences in torque that could potentially be applied when inserting new connectors.

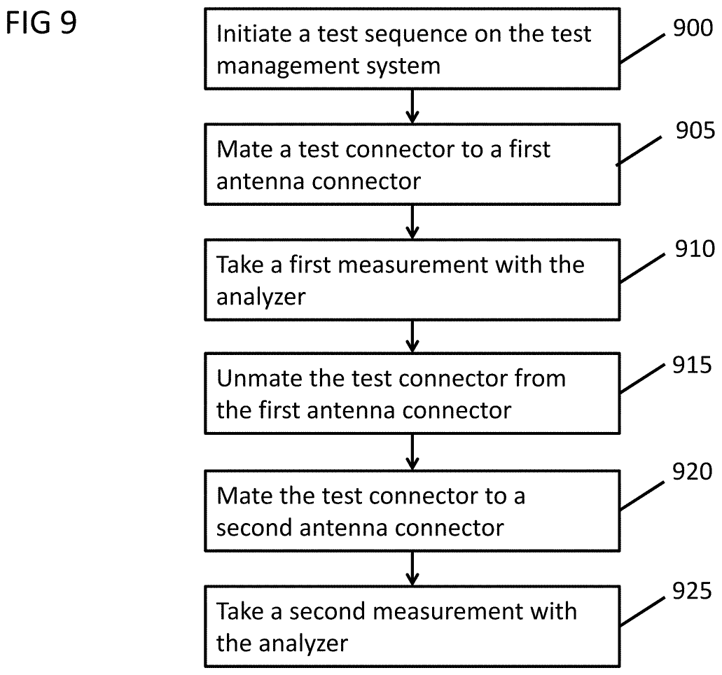

FIGS. 9-11 are flowcharts that illustrate operations of a test setup according to some embodiments of the inventive concept. Referring to FIG. 9 an operator may initiate a test sequence on the test management system (block 900). The test sequence can be one that an operator previously configured to perform all of the necessary steps to test a number of antenna ports. After the test sequence is started, the test management system is able to control the test fixture and analyzer independently to test the ports. This includes mating a test connector to an antenna connector by moving the test connector along the linear track, and then moving it forward to mate with the selected antenna connector (block 905). Once connected, the test management system can signal to the analyzer to take a measurement (block 910). Once the measurement is taken, the test management system can retrieve data from the analyzer and correlate that data with the port currently under test. The test management system can then have the test fixture unmate the connectors (block 915), and mate a different pair of connectors (block 920) to perform another measurement (block 925).

Other methods require an operator to enter the test chamber every time a different antenna port needs to be tested. This may require extra time, and for an operator to be available when it is time to change ports. It also introduces the possibility of operator error. Embodiments of the inventive concept may provide an automated testing method, which may both improve testing efficiency and testing accuracy due to the test setup reducing the areas on which PIM may be introduced.

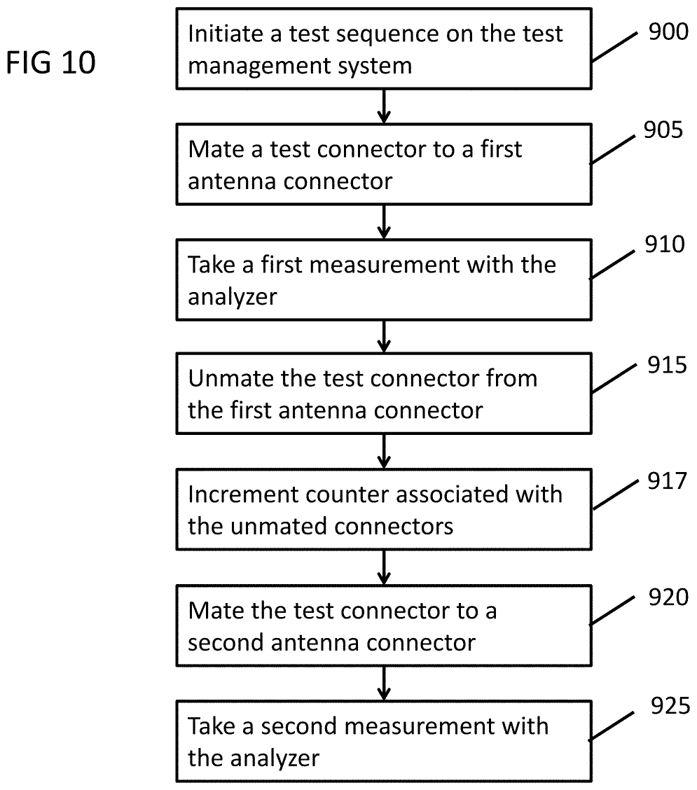

FIG. 10 is similar to FIG. 9, but in addition to performing the test sequence as described above, the test fixture can increment a counter to keep track of how many connection cycles each connector has undergone (block 917). Connectors may degrade after a number of connection cycles, which can introduce errors into measurements. To reduce or prevent these errors, it may be desirable to replace cables and/or connectors before they degrade to the point of causing errant measurements. Keeping track of how many cycles a connector has gone through can give an indication to an operator of when to change the cables and/or connectors. Either an operator can determine themselves that a connector should be replaced based on the cycle count, or the test management system can provide an alert when a threshold has been passed in accordance with various embodiments of the inventive concept

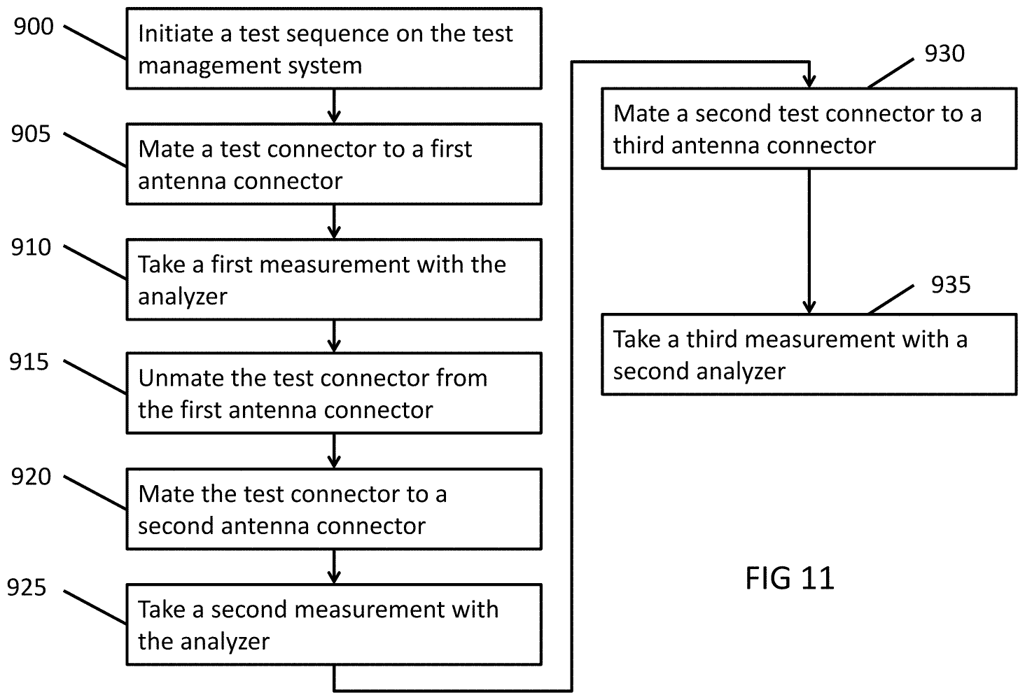

FIG. 11 is similar to FIG. 9, but the testing operations may be performed using additional antenna connectors to test additional antenna ports. The embodiments of FIG. 11 include three antenna connectors in which a second test connector is mated to a third antenna connector (block 930), but it will be understood that more connectors could be included in accordance with various embodiments of the inventive concept. The embodiments of FIG. 11 also include making a measurement with a second analyzer (block 935). This may allow for different frequency ranges to be tested during the same test sequence. It will be understood that additional analyzers could be used to further expand the frequency ranges tested.

In some embodiments, multiple test fixtures can be included in the test setup so that a larger number of antenna ports can be tested in a single test sequence. Test fixtures can be connected to different analyzers in parallel, or test fixtures can be daisy chained. When daisy chained, a single analyzer can be used to test a larger number of antenna ports than is possible with a single test fixture.

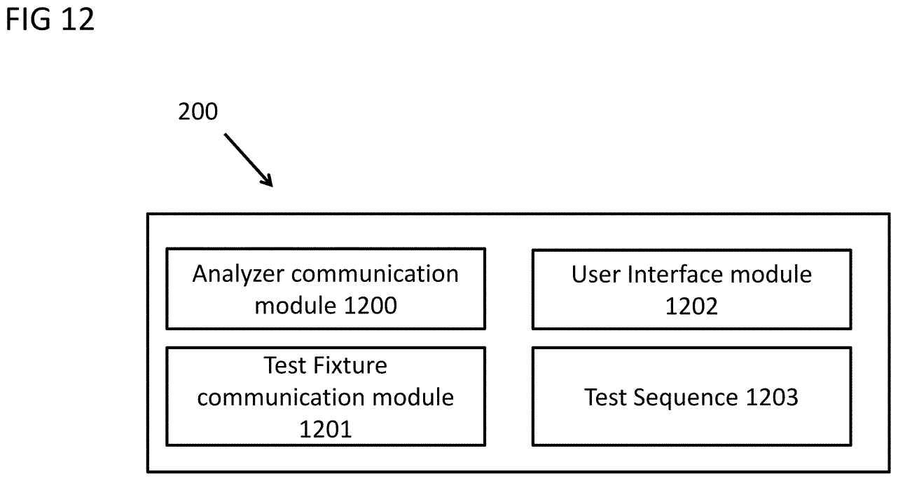

Referring to FIG. 12, a test management system 200 may comprise a number of modules for controlling the test setup. The test management system 200 may include one or more processor circuits and one or more memory circuits. The processor circuits may be configured to execute computer readable program code to perform at least some of the operations described herein. The test management system 200 modules described below may be implemented as computer readable code stored in a computer readable medium for execution by one or more processors and/or may be implemented as one or more circuits configured to perform at least some of the operations described herein.

An analyzer communication module 1200 may be configured to communicate with the analyzer 201A. This communication may include commands to the analyzer, such as selecting a frequency range, calibration, or starting a measurement. Communication from the analyzer 201A to the analyzer communication module 1200 may include data from measurements, identifying information, etc.

Test fixture communication module 1201 may be configured to communicate with the test fixture controller 507. Communication to the test fixture controller 507 may include commands to mate a pair of connectors in specified positions, reset connection counters, etc. Communication from the test fixture controller 507 to the test fixture communication module 1201 may include information about the position of the connectors, and connection cycle counts for each of the connectors, etc.

User interface module 1202 may be configured to provide an interface for an operator to configure and run tests. Configuring a test may include indicating which antenna ports are inserted into which test fixture slots, which analyzers are inserted into test connector slots, which ports need testing with which analyzers, etc. Running a test once it is configured may be performed with a single button press. It will be understood, however, that there may be test sequences that may require user interaction during the test sequence in accordance with some embodiments.

The user interface module 1202 may also indicate to an operator the number of connection cycles each connector has undergone. The user interface module 1202 may provide an alert for when a connector and/or cable needs to be replaced. Error messages may also be provided, for example, if an expected connection is missing, or the analyzer fails to communicate, etc.

The user interface module 1202 may additionally display the parameters of a test sequence. An operator may be able to configure a number of different test sequences. The user interface module 1202 may allow the operator to select which test to reconfigure or run.

The user interface module 1202 may display results of the test sequence either as the measurements are performed, or after the entire test sequence is performed, or both. Test results may include raw measurement data, graphs of the data, and pass/fail indicators if the measured values are below or above specified thresholds.

Test sequence module 1203 may be configured to provide the test sequence currently being configured and/or performed.

### Further Definitions and Embodiments

The terminology used herein is for the purpose of describing particular aspects only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Like reference numbers signify like elements throughout the description of the figures.

It will be understood that, although the terms “first,” “second,” etc. may be used herein to describe various elements, these elements should not be limited by these terms. These terms are only used to distinguish one element from another. Thus, a first element could be termed a second element without departing from the teachings of the inventive subject matter.

It will be understood that when an element is referred to as being “on”, “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

In the above-description of various embodiments of the present disclosure, aspects of the present disclosure may be illustrated and described herein in any of a number of patentable classes or contexts including any new and useful process, machine, manufacture, or composition of matter, or any new and useful improvement thereof. Accordingly, aspects of the present disclosure may be implemented entirely hardware, entirely software (including firmware, resident software, micro-code, etc.) or combining software and hardware implementation that may all generally be referred to herein as a “circuit,” “module,” “component,” or “system.” Furthermore, aspects of the present disclosure may take the form of a computer program product comprising one or more computer readable media having computer readable program code embodied thereon.

Any combination of one or more computer readable media may be used. The computer readable media may be a computer readable signal medium or a computer readable storage medium. A computer readable storage medium may be, for example, but not limited to, an electronic, magnetic, optical, electromagnetic, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), an appropriate optical fiber with a repeater, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable instruction execution apparatus, create a mechanism for implementing the functions/acts specified in the flowchart and/or block diagram block or blocks.

These computer program instructions may also be stored in a computer readable medium that when executed can direct a computer, other programmable data processing apparatus, or other devices to function in a particular manner, such that the instructions when stored in the computer readable medium produce an article of manufacture including instructions which when executed, cause a computer to implement the function/act specified in the flowchart and/or block diagram block or blocks. The computer program instructions may also be loaded onto a computer, other programmable instruction execution apparatus, or other devices to cause a series of operational steps to be performed on the computer, other programmable apparatuses or other devices to produce a computer implemented process such that the instructions which execute on the computer or other programmable apparatus provide processes for implementing the functions/acts specified in the flowchart and/or block diagram block or blocks.

The flowchart and block diagrams in the figures illustrate the architecture, functionality, and operation of possible implementations of systems, methods, and computer program products according to various aspects of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The aspects of the disclosure herein were chosen and described to best explain the principles of the disclosure and the practical application, and to enable others of ordinary skill in the art to understand the disclosure with various modifications as are suited to the particular use contemplated.

The foregoing is illustrative of the present invention and is not to be construed as limiting thereof. Although example embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. The invention is defined by the following claims, with equivalents of the claims to be included therein.

1. A test fixture, comprising:
a first body comprising a plurality of slots that are configured to receive a plurality of antenna connectors, respectively;
a second body opposing the first body and comprising a slot that is configured to receive a test connector; and
a lateral positioning component that is configured to move the second body relative to the first body so as to position the test connector across from one of the plurality of antenna connectors;
wherein the second body is further configured to push the test connector into the one of the plurality of antenna connectors across from the test connector so as to mate the test connector to the one of the plurality of antenna connectors.

2. The test fixture of claim 1, wherein the plurality of antenna connectors comprise a plurality of blind mate connectors.

3. The test fixture of claim 1, wherein each of the plurality of antenna connectors comprises a flange portion; and
wherein the plurality of slots are configured to receive the plurality of flange portions of the plurality of antenna connectors, respectively, therein.

4. (canceled)

5. The test fixture of claim 1, wherein each of the plurality of antenna connectors comprises a beveled countersink opening that is configured to receive the test connector therein.

6. The test fixture of claim 1, wherein the plurality of antenna connectors are coupled to a plurality of biasing springs, respectively, which are configured to urge the plurality of antenna connectors towards the second body.

7. (canceled)

8. The test fixture of claim 1, wherein the lateral positioning component comprises:
a worm drive coupled to the second body; and
a motor connected to the worm drive and configured to rotate the worm drive to move the second body relative to the first body.

9. The test fixture of claim 8, wherein the motor is configured to rotate the worm drive responsive to a motor operation signal generated by a test controller.

10. The test fixture of claim 9, wherein the test controller is configured to count a number of times the test connector has been mated to ones of the plurality of connectors.

11. The test fixture of claim 1, wherein the slot in the second body is a first slot and the test connector is a first test connector; and
wherein the second body further comprises a second slot that is configured to receive a second test connector.

12. The test fixture of claim 11, wherein the second test connector does not mate with any of the plurality of antenna connectors when the first test connector mates with the one of the plurality of antenna test connectors.

13. (canceled)

14. A method for measuring an attribute of multiple antenna ports, comprising:
automatically mating a test connector to a first antenna connector, in response to initiation of a test sequence;
taking a first measurement with the analyzer;
automatically unmating the test connector from the first antenna connector;
automatically mating the test connector to a second antenna connector; and
taking a second measurement with a first analyzer.

15. The method of claim 14, further comprising counting a number of times each cable is mated.

16. The method of claim 14, wherein controlling the test fixture and taking a measurement are performed without the intervention of an operator after an initial command.

17. The method of claim 14, further comprising, in response to initiating the test sequence:
automatically mating a second test connector to a third antenna connector; and
taking a third measurement with a second analyzer.

18. The method of claim 17, wherein the first analyzer is configured to measure a different frequency range than the second analyzer.

19. An antenna test system, comprising:
a test chamber;
a test fixture inside the test chamber;
an antenna inside the test chamber;
an analyzer outside the test chamber;
a plurality of jumper cables connected from a plurality of antenna ports to the test fixture;
at least one test cable connected from the test fixture, through a conduit, to the analyzer; and
a computer;
wherein the computer is configured to send a command to the test fixture;
wherein the test fixture is configured to mate the at least one test cable to one of the plurality of jumper cables in response to the command;
wherein the test fixture is further configured to mate the at least one test cable to a second one of the plurality of jumper cables in response to east least one subsequent command from the computer without an operator entering the test chamber.

20. The antenna test system of claim 19, wherein the test fixture is configured to move a first connector of the at least one test cable along a linear track to align with a selected second connector of the jumper cables.

21. The antenna system of claim 17, wherein the test fixture is configured to move the first connector towards the second connector to mate the first connector to the second connector.

22. The antenna system of claim 19, wherein the analyzer is a first analyzer and the at least one test cable is a first test cable, the system further comprising:
a second analyzer; and
a second test cable, the second test cable being connected from the test fixture, through a conduit, to the second analyzer;
wherein the first analyzer is configured to operate in a first frequency range; and
wherein the second analyzer is configured to operate in a second frequency range.

23. The antenna system of claim 22, wherein the first frequency range and the second frequency range do not overlap.
